(19) United States
(12) Patent Application Publication
(10) Pub. No.: US 2019/0194818 A1
(43) Pub. Date: Jun. 27, 2019

(54) METHOD OF PRODUCING SILICON CARBIDE SINGLE CRYSTAL

(71) Applicant: SHOWA DENKO K.K., Tokyo (JP)

(72) Inventor: Takahiro IGI, Hikone-shi (JP)

(73) Assignee: SHOWA DENKO K.K., Tokyo (JP)

(21) Appl. No.: 16/225,967

(22) Filed: Dec. 19, 2018

(30) Foreign Application Priority Data
Dec. 25, 2017 (JP) 2017-248349

(51) Int. Cl. C30B 23/00; C30B 29/36; H01L 21/02

(52) U.S. Cl. CPC C30B 23/00; H01L 21/02378; C30B 29/36

(57) ABSTRACT

A method of producing a silicon carbide single crystal capable of producing a silicon carbide single crystal substrate in which the number of occurrences of basal plane dislocations is reduced to 100 cm⁻² or less is provided. The method of producing a silicon carbide single crystal includes in this order: a preliminary heating step of heating a silicon carbide seed crystal to a temperature of 2000° C. or higher, before growing the silicon carbide single crystal on the silicon carbide seed crystal, in the state in which the silicon carbide seed crystal is attached on an arranged graphite member on one side of a crucible, and a silicon carbide raw material is provided on the other side; and a cooling step of cooling the silicon carbide seed crystal to a room temperature.

### TECHNICAL FIELD

The present invention relates to a method of producing a silicon carbide single crystal.

Priority is claimed on Japanese Patent Application No. 2017-248349, filed on Dec. 25, 2017, the content of which is incorporated herein by reference.

### BACKGROUND ART

Silicon carbide (SiC) which is a semiconductor material having a larger band gap than silicon (Si) is widely used as a device substrate. For this reason, research has been conducted to fabricate various devices, such as power devices, high frequency devices, high temperature operation devices and the like, using a silicon carbide single crystal substrate.

These devices are fabricated using SiC epitaxial wafers. The SiC epitaxial wafers are obtained by forming an epitaxial layer (film) to be an active region of a device on a silicon carbide single crystal substrate by chemical vapor deposition (CVD) or the like. The silicon carbide single crystal substrate is obtained by processing from a bulk single crystal of silicon carbide grown by a sublimation method or the like.

In a silicon carbide single crystal substrate, basal plane dislocations, and crystal defects called micropipes and the like generally exit inside. It is a problem that these crystal defects propagate to the SiC epitaxial layer, and as a result, the characteristics of the SiC device deteriorate.

Patent Document 1 discloses a technique of uniformly growing a silicon carbide single crystal over the entire surface of a seed crystal by adjusting an adhesion state between the seed crystal and a pedestal to increase the amount of heat transfer along the surface of the seed crystal, in order to reduce basal plane dislocations generated in the silicon carbide single crystal substrate.

Patent Document 2 discloses a technique of coating micropipe defects in a silicon carbide seed crystal by growing a silicon carbide single crystal in a silicon rich atmosphere in order to avoid the influence of the micropipe defects.

Patent Document 3 discloses a technique of further regrowing by annealing treatment on a grown silicon carbide single crystal in order to prevent sublimation of the surface of the silicon carbide single crystal and cracking due to thermal stress.

[Patent Document 1] Japanese Unexamined Patent Application Publication No. 2015-74602

[Patent Document 2] Japanese Unexamined Patent Application Publication No. 2001-158695

[Patent Document 3] Japanese Unexamined Patent Application Publication No. 2014-34504

### SUMMARY OF THE INVENTION

However, it is difficult to reduce the occurrence of defects due to basal plane dislocations to a density of 100 cm⁻² or less by using any one of the disclosed techniques. A technique to suppress such defects is in demand.

The present invention has been made in view of the above circumstances, and it is an object of the present invention to provide a method of producing a silicon carbide single crystal capable of producing a silicon carbide single crystal substrate in which the number of occurrences of basal plane dislocations is reduced to 100 cm⁻² or less.

In order to solve the above problem, the present invention includes the following embodiments.

(1) A method of producing a silicon carbide single crystal using a sublimation method, comprising in this order:

a preliminary heating step of heating a silicon carbide seed crystal to a temperature of 2000° C. or higher, before growing the silicon carbide single crystal on the silicon carbide seed crystal, in the state in which the silicon carbide seed crystal is attached on an arranged graphite member on one side of a crucible, and a silicon carbide raw material is provided on the other side; and

a cooling step of cooling the silicon carbide seed crystal to a room temperature.

(2) The method of producing a silicon carbide single crystal according to (1), in the preliminary heating step and the cooling step, the pressure in the crucible can be 150 Torr or less.

(3) The method of producing a silicon carbide single crystal according to (1) or (2), wherein a heating rate in the preliminary heating step is set to 50° C./min or more and 1200° C./min or less.

(4) The method for producing a silicon carbide single crystal according to any one of (1) to (3), a cooling rate in the cooling step is set to 50° C./min or more and 400° C./min or less.

In the method of producing a silicon carbide single crystal by a sublimation method, a distortion tends to occur in a silicon carbide seed crystal attached to the graphite member (pedestal) due to difference in a coefficient of thermal expansion from the graphite member. In the present invention, this distortion can be relaxed by performing preliminary heating to raise the temperature to 2000° C. or higher and cooling it to bring a temperature to room temperature before growing the silicon carbide single crystal. Accordingly, in the present invention, because it is possible to grow a silicon carbide single crystal on a small seed crystal lattice distortion, the effect of stress due to distortion is reduced. As a result, the defect density due to basal plane dislocations generated in the grown silicon carbide single crystal can be reduced to 100 cm⁻² or less.

### BRIEF DESCRIPTION OF THE DRAWINGS

FIGS. 1(a) and (b) are views showing the method of producing a silicon carbide single crystal according to one embodiment of the present invention.

FIG. 2(a) is a photographic image of a surface of a silicon carbide seed crystal before preliminary heating step in the method for producing a silicon carbide single crystal of the present invention; and FIG. 2(b) is a photographic image of the surface of the silicon carbide seed crystal after the preliminary heating step in the method for producing the silicon carbide single crystal of the present invention.

FIG. 3 is a graph showing basal plane dislocation densities at each position of a silicon carbide single crystal ingot obtained by carrying out the present invention.

### DETAILED DESCRIPTION OF THE INVENTION

Hereinafter, the present invention will be described in detail with reference to the drawings as appropriate. In order to make the features of the present invention easy to understand, the drawings used in the following description sometimes show the characteristic portions in an enlarged manner for convenience, and the dimensional ratios and the like of the respective constituent elements are different from actual ones. In addition, the materials, dimensions, and the like exemplified in the following description are mere examples, and the present invention is not limited thereto, and can be carried out by appropriately changing within the range that achieves the effects of the present invention.

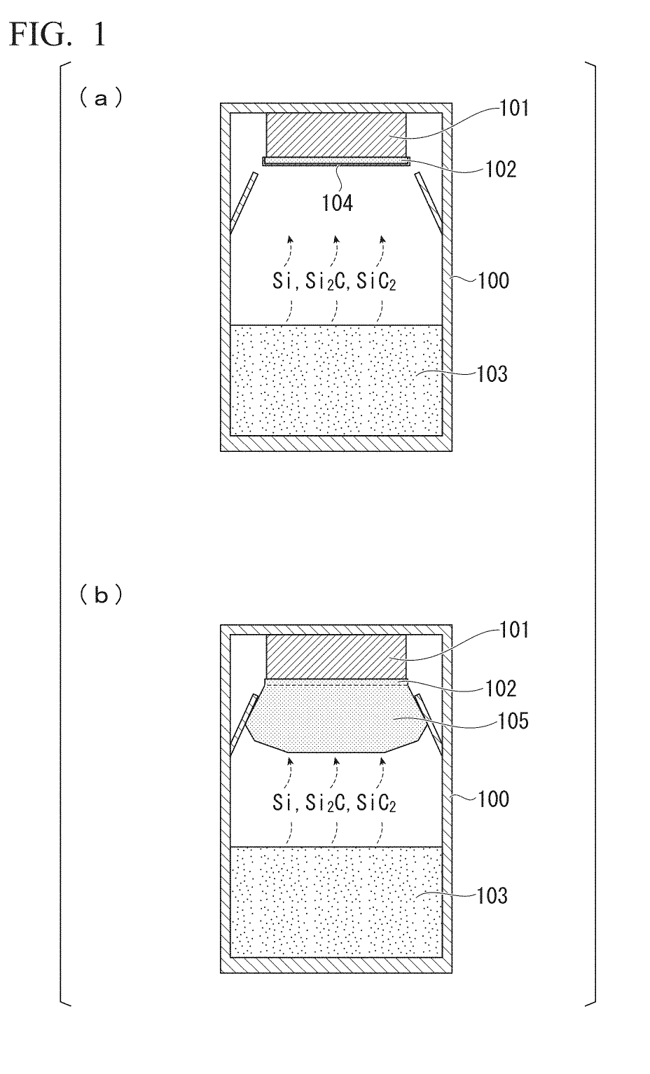

FIG. 1(a) and (b) are views showing a method of producing a silicon carbide single crystal using a sublimation method according to an embodiment of the present invention. The sublimation method is a method including placing a seed crystal made of a single crystal of silicon carbide on a pedestal (graphite member) disposed in a crucible made of graphite, supplying a sublimation gas (Si, Si₂C, SiC₂, etc.) sublimed from a powdered raw material in the crucible by heating the crucible 100 to the seed crystal, and growing the seed crystal into a larger SiC single crystal. FIG. 1(a) shows a state in which the silicon carbide seed crystal 102 is attached on a pedestal 101 arranged on one side in the crucible 100 and the silicon carbide raw material 103 is disposed on the other side.

The pressure inside the crucible 100 can be adjusted by using an exhaust device (not shown), and it is preferable to set it to 1 Torr or more and 150 Torr or less.

Prior to a main heating step of growing silicon carbide single crystal on the silicon carbide seed crystal 102 according to the present embodiment, in the state shown in FIG. 1(a), a preliminary heating step is carried out at a temperature equivalent to the heating temperature of the main heating step, and then a cooling step is carried out. First, the preliminary heating step and the cooling step will be described.

(Preliminary Heating Step)

In the preliminary heating step, a temperature in the crucible 100 is heated from a room temperature to a temperature between 2000° C. and 2500° C., and the temperature is maintained for a certain period of time to heat the silicon carbide seed crystal 102. The heating rate is preferably 50° C./min or more and 1200° C./min or less. The heating time excluding a temperature rising time, that is, the heating time at a constant temperature is preferably 30 minutes or more and 90 minutes or less.

The heating step may be carried out, for example, by arranging a coil around the crucible 100 and using an induction heating system. The induction heating system is a heating system that an object is heated by the following method. A magnetic field is generated by applying a high frequency current to the coil. The magnetic field is applied to an object to be heated, and then an electric current is induced. Then, heat is generated in the object to be heated by utilizing the current induced therein.

(Cooling Step)

In the next cooling step, the interior of the crucible 100 is cooled to a room temperature, and the room temperature is maintained for a certain period of time to cool the silicon carbide seed crystal 102. It is preferable that the cooling rate be 50° C./min or more and 400° C./min or less.

The cooling step may be carried out, for example, by opening inside of the crucible 100 to the atmosphere or by supplying a refrigerant gas such as argon, nitrogen, hydrogen, or the like into the crucible 100. The cooling step by supplying the refrigerant gas does not need to perform evacuation of the crucible 100 prior to the main heating step, and therefore, the three steps including the preliminary heating step, the cooling step and the main heating step may be carried out continuously. Therefore, the production time can be shortened. From this viewpoint, the cooling method by supplying a refrigerant gas is preferable.

A carbide film 104 composed mainly of carbon is formed on a surface of the silicon carbide seed crystal 102 obtained by carrying out the cooling step, wherein the surface is a surface to be exposed to an atmosphere in the crucible 100. The silicon carbide seed crystal 102 is in a state that it appears cloudy as compared with a silicon carbide seed crystal obtained by the conventional method. It is considered that the carbide film 104 is formed by adhering a part of gas generated from the silicon carbide raw material in the preliminary heating step and solidifying the gas in the subsequent cooling step.

(Main Heating Step)

Next, a main heating step for growing a silicon carbide single crystal on the silicon carbide seed crystal 102 will be described. FIG. 1 (b) shows a state in which the silicon carbide single crystal 105 is grown on the silicon carbide seed crystal 102 by performing the main heating by using a sublimation method. The silicon carbide seed crystal 102 in the main heating step is the silicon carbide seed crystal which has been subjected to the preliminary heating step and the cooling step. The silicon carbide seed crystal 102 and the pedestal 101 thereof after the cooling step may be continuously used. The constituent elements (atmosphere in the crucible 100, silicon carbide raw material 103, and peripheral members, etc.) other than the silicon carbide seed crystal 102 and the pedestal 101 may be replaced after the cooling step and before the main heating step.

In the main heating step, the temperature inside the crucible 100 is raised again from a room temperature to a temperature between 2000° C. and 2500° C., and the heating state of the silicon carbide seed crystal 102 is maintained for a certain period of time to heat. Thus, the silicon carbide single crystal 105 is grown. The heating rate is preferably 50° C./min or more and 1200° C./min or less. A heating time except for the temperature rising time, that is, the time for growing the single crystal may be set according to the length of the desired silicon carbide single crystal. After heating for a certain period of time, it is cooled and an ingot of silicon carbide single crystal is taken out. It is preferable that the cooling rate be 50° C./min or more and 400° C./min or less.

A silicon carbide single crystal substrate can be obtained by cutting out a prescribed portion of the ingot of the silicon carbide single crystal obtained by carrying out the main heating step.

In the method of producing the silicon carbide single crystal by the sublimation method, distortion tends to occur in the silicon carbide seed crystal attached to the graphite member (pedestal) due to difference of thermal expansion coefficients between the silicon carbide seed crystal and the graphite member. In this embodiment, this distortion can be relaxed by performing preliminary heating for raising the temperature to 2000° C. or higher and cooling for returning the temperature to a room temperature before growing the silicon carbide single crystal. Accordingly, in this embodiment, since it is possible to grow a silicon carbide single crystal on a seed crystal lattice having a small distortion, the effect of stress due to distortion is reduced. As a result, the defect density due to the basal plane dislocation generated in the grown silicon carbide single crystal can be reduced to 100 cm⁻² or less.

Further, in the present embodiment, since the preliminary heating is performed in a state where the silicon carbide raw material 103 is supplied into the crucible 100, gas of the silicon carbide raw material 103 is generated during the preliminary heating. The gas adheres to the surface of the silicon carbide seed crystal 102 and becomes a carbide film 104 in the cooling step. Therefore, in the present embodiment, since the surface of the silicon carbide seed crystal 102 is protected by the carbide film 104, deterioration is suppressed. Therefore, it is possible to obtain an effect of suppressing occurrence of basal plane dislocations starting from defects caused by deterioration at an initial growth stage. As a result, basal plane dislocations can be reduced from a vicinity of the seed crystal of the silicon carbide single crystal ingot.

### EXAMPLE

Hereinafter, the effect of the present invention will be made clear by Examples. It should be noted that the present invention is not limited to the following examples, but can be carried out with appropriate modifications within the scope not changing the gist thereof.

### Example 1

In the production method of the above embodiment, an ingot of silicon carbide single crystal was produced by carrying out from the preliminary heating to the main heating step. The pressure inside the crucible was set to 140 Torr in the all of the steps.

The preliminary heating step was performed by an induction heating system using a coil. A heating rate in the preliminary heating step was set to 420° C./min and an interior of the crucible was heated at 2110° C. for 60 minutes.

The cooling step was performed by flowing an argon gas and a nitrogen gas (refrigerant gases) into the crucible. The cooling rate in the cooling step was 110° C./min.

In the main heating step, a silicon carbide raw material and a crucible member were newly provided, and the induction heating method using a coil was carried out similarly to the preliminary heating step. The heating rate in the main heating step was 420° C./min and the heating time except for the temperature rising time was 90 minutes. The silicon carbide seed crystal having undergone the preliminary heating step and the cooling step were continuously used as the silicon carbide seed crystal in the main heating step.

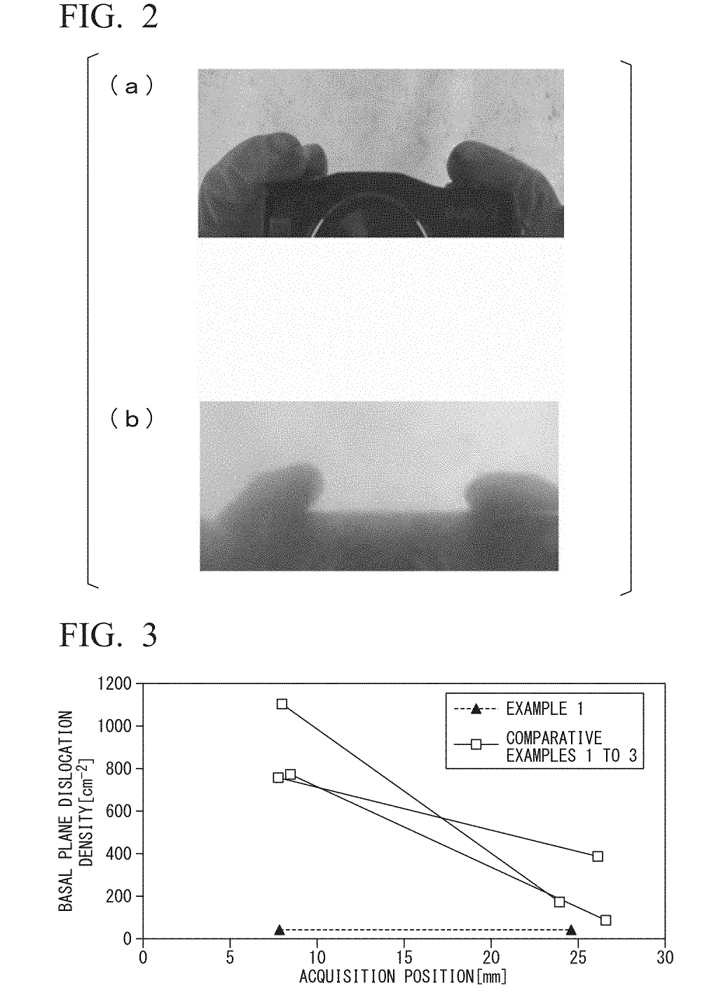

FIG. 2(a) is a photographic image of the surface of the silicon carbide seed crystal before the preliminary heating step, and FIG. 2(b) is a photographic image of the surface of the silicon carbide seed crystal after the preliminary heating. The black part is an image of a camera used for taking pictures. From comparison of the two photographic images, the surface of the silicon carbide seed crystal after the preliminary heating is rougher than that before the preliminary heating step. When it was viewed from an oblique, it appears as a cloudy color like a grey color due to reflection of light. The cause of roughness is a carbide film containing carbon as a main component. It is considered that this carbide film is obtained by adhering a gas generated from the silicon carbide raw material in the preliminary heating step and solidifying the gas in the subsequent cooling step.

At 24.5 mm growth position of the ingot (distance from the silicon carbide seed crystal), a silicon carbide single crystal substrate A was obtained by cutting out a (0001) plane substrate, and then mirror-polishing it. A silicon carbide single crystal substrate B was obtained in the same manner at 7.8 mm growth position of the ingot (distance from the silicon carbide seed crystal).

### Comparative Examples 1 to 3

In the production method of the above embodiment, three ingots of silicon carbide single crystal substrates which underwent only the main heating step were produced. From obtained ingots, silicon carbide single crystal substrates were obtained by cutting out one by one in the same manner as in Example 1. The production conditions were the same as those in Example 1, except for that the preliminary heating step and the cooling step were not performed.

(Evaluation of Defect Density of Silicon Carbide Single Crystal Substrate)

After the silicon carbide single crystal substrate A obtained in Example 1 was subjected to molten KOH etching, a basal plane dislocation density and a threading dislocation density were measured by an optical microscope method. The molten KOH etching was carried out according to the method described in a non-patent document of J. Takahashi et al., Journal of Crystal Growth, 135, (1994), 61-70, by immersing the samples for 10 minutes in molten KOH at 530° C. Dislocation defects were classified based on a shape of etch pit, and for example, a pit having a shell shape was classified to a basal plane dislocation and a pit having a hexagonal shape was classified to a threading dislocation.

The black spot of the transmitted X-ray topographic image on the (1-100) diffraction plane was classified to a through screw dislocation as a dislocation defect.

At positions of 37 points on the silicon carbide single crystal substrate A obtained in Example 1, a viewing area at each one point was set to 0.014595 cm², and then each defect density at each one point of the 37 points was obtained by measuring the number of defects in the viewing area at the point. The 37 points include a center point of the surface, a first 18 points (at same interval: 5 mm) located on a line which was parallel to OF (orientation flat) and through the center point, and a second 18 points (at same interval: 5 mm) located on a line which was perpendicular to OF (orientation flat) and through the center point. The defect densities calculated from the number of all the etch pits observed with the predetermined viewing area was an etch pit density [cm⁻²]. The defect densities calculated from the number of basal plane dislocations observed with the predetermined viewing area was a basal plane dislocation density [cm⁻²]. Using each value of the 37 points, the average value of them was calculated.

In addition, regarding a through thread screw dislocation density of the silicon carbide single crystal substrate A obtained in Example 1, five thread screw dislocation densities at five points were measured by using a view area of 0.25 cm² at each point. The above five points include one center point, a first two points (25 mm from the center point) which were on a straight line parallel to OF and through the center point, and a second two points (25 mm from the center point) which were on a vertical straight line and through the center point. A defect density calculated from the number of screw thread screw dislocations observed by using the predetermined viewing area was taken as a threading screw dislocation density [cm⁻²]. Using each value of 5 points, the average value was calculated.

The calculation results are shown in Table 1. In a similar manner, the silicon carbide single crystal substrate B obtained in Example 1 was also evaluated, and the results are shown in Table 1 and FIG.3.

TABLE 1

| Acquisition Position | EPD | BPD | TSD |
|---|---|---|---|
| [mm] | [cm⁻²] | [cm⁻²] | [cm⁻²] |
| 24.6 | 2584 | 43 | 265 |
| 7.8 | 4688 | 46 | 280 |

EPD: Etch Pit Density
BPD: Basal Plane Dislocation Density
TSD: Penetrating Screw Dislocation Density

At any acquisition positions, the number of defects due to basal plane dislocation was remarkably smaller than other defects and was suppressed to 50 cm⁻² or less.

For the silicon carbide single crystal substrate obtained in Comparative Examples 1 to 3, defect densities due to the basal plane dislocation were calculated by using the same method as in Example 1. The calculation results are shown in the graph of FIG. 3 together with the calculation results in Example 1. In the graph, the horizontal axis shows acquisition positions (corresponding to the distance from the silicon carbide seed crystal) [mm] of the substrate in the ingot, and the vertical axis shows calculated defect densities (basal plane dislocation density) [cm⁻²]. The triangle plot corresponds to Example 1 and the rectangular plot corresponds to Comparative Examples 1 to 3.

In Comparative Examples 1 to 3, the defect densities due to the basal plane dislocation have a large value of about 800 to 1100 cm⁻² when the substrate was acquired at a position of about 8 mm away from the silicon carbide seed crystal (corresponding to the plot on the left side). This defect densities tend to become smaller as going away from the silicon carbide seed crystal, and it is about 100 to 400 cm⁻² at a position of about 25 mm far away from the silicon carbide seed crystal (corresponding to the plot on the right side).

On the other hand, the defect densities in Example 1 were less dependent on the position than those in Comparative Examples 1 to 3, and the defect density at any one of acquisition positions has a value smaller than 50 cm⁻². The silicon carbide seed crystal distortion due to difference in thermal expansion coefficient between the silicon carbide seed crystal and the pedestal was relaxed by raising and lowering the temperature with a temperature difference of 2000° C. or more at steps before growing the silicon carbide single crystal. As a result, the influence of stress which causes dislocation was reduced.

Further, in the steps of raising and lowering the temperature, the carbide film containing silicon carbide raw material in the crucible as a main component was formed on the surface of the silicon carbide seed crystal. The carbide film which functions as a protective film also have an effect of suppressing deterioration of the surface leading to occurrence of basal plane dislocation.

### INDUSTRIAL APPLICABILITY

The present invention can be utilized in growing a SiC single crystal by a sublimation method. The present invention provides a method which significantly reduces occurrence of basal plane dislocations which affects the characteristics of the device which using a SiC single crystal, and as a result, a manufacturing yield can be greatly improved.

### EXPLANATION OF SIGN

100 Crucible

101 Pedestal

102 Silicon carbide seed crystal

103 Silicon carbide raw material

104 Carbide film

105 Silicon carbide single crystal

1. A method of producing a silicon carbide single crystal using a sublimation method, comprising in this order:
a preliminary heating step of heating a silicon carbide seed crystal to a temperature of 2000° C. or higher, before growing the silicon carbide single crystal on the silicon carbide seed crystal, in the state in which the silicon carbide seed crystal is attached on an arranged graphite member on one side of a crucible, and a silicon carbide raw material is provided on the other side; and
a cooling step of cooling the silicon carbide seed crystal to a room temperature.

2. The method of producing a silicon carbide single crystal according to claim 1, wherein in the preliminary heating step and the cooling step, a pressure in the crucible is set to 150 Torr or less.

3. The method of producing a silicon carbide single crystal according to claim 1, wherein the heating rate in the preliminary heating step is set to 50° C./min or more and 1200° C./min or less.

4. The method of producing a silicon carbide single crystal according to claim 2, wherein a heating rate in the preliminary heating step is set to 50° C./min or more and 1200° C./min or less.

5. The method for producing a silicon carbide single crystal according to claim 1, wherein a cooling rate in the cooling step is set to 50° C./min or more and 400° C./min or less.

6. The method for producing a silicon carbide single crystal according to claim 2, wherein a cooling rate in the cooling step is set to 50° C./min or more and 400° C./min or less.
